(19) United States
(12) Patent Application Publication
(10) Pub. No.: US 2023/0411379 A1
(43) Pub. Date: Dec. 21, 2023

(54) SEMICONDUCTOR INTEGRATED CIRCUIT DEVICE

(71) Applicant: Socionext Inc., Kanagawa (JP)

(72) Inventor: Hideyuki KOMURO, Yokohama-shi (JP)

(21) Appl. No.: 18/458,672

(22) Filed: Aug. 30, 2023

Related U.S. Application Data
(63) Continuation of application No. PCT/JP2022/007342, filed on Feb. 22, 2022.

(30) Foreign Application Priority Data
Mar. 5, 2021 (JP) 2021-035507

(51) Int. Cl. H01L 27/02; H01L 27/092; H01L 23/522

(52) U.S. Cl. CPC H01L 27/0207; H01L 27/0924; H01L 27/0925; H01L 23/5221

(57) ABSTRACT

In a semiconductor integrated circuit device using buried power lines, a first standard cell includes a buried power line extending in the X direction to supply VDD1, and a transistor is supplied with VDD1 from the buried power line. A second standard cell includes a buried power line extending in the X direction to supply VDD1 and an upper-layer power line formed in a layer above the buried power line to supply VDD. A transistor of the second standard cell is supplied with VDD from the upper-layer power line. The upper-layer power line overlaps the buried power line in planar view.

### CROSS-REFERENCE TO RELATED APPLICATIONS

This is a continuation of International Application No. PCT/JP2022/007342 filed on Feb. 22, 2022, which claims priority to Japanese Patent Application No. 2021-035507 filed on Mar. 5, 2021. The entire disclosures of these applications are incorporated by reference herein.

### BACKGROUND

The present disclosure relates to a semiconductor integrated circuit device provided with standard cells.

As a method for forming a semiconductor integrated circuit on a semiconductor substrate, a standard cell method is known. The standard cell method is a method in which basic units (e.g., inverters, latches, flipflops, and full adders) having specific logical functions are prepared in advance as standard cells, and a plurality of such standard cells are placed on a semiconductor substrate and connected through interconnects, thereby designing an LSI chip.

Also, for higher integration of a semiconductor integrated circuit device, it is proposed to use, for standard cells, buried power rails (BPRs) that are power lines laid in a buried interconnect layer, not power lines laid in a metal interconnect layer formed above transistors as conventionally done.

U.S. Patent Application Publication No. 2019/0080969 (FIG. 1E) (Patent Document 1) discloses a configuration of a block constituted by standard cells, in which buried power rails are used and connected to sources of transistors and further connected to power lines laid in an upper interconnect layer.

Japanese Unexamined Patent Publication No. 2007-329170 (FIG. 3) (Patent Document 2) discloses a technology in which, in a semiconductor integrated circuit device, while power supply to a given circuit region is stopped for reduction in power consumption, a relay circuit to which power supply is not stopped is provided in this circuit region.

Conventionally, however, in a semiconductor integrated circuit device using buried power rails, no study has been made on the layout structure, etc. of such a relay circuit as described above in a configuration where power supply to a given circuit region is stopped.

Also, in the technology disclosed in Patent Document 2, since the power line becomes discontinuous in the portion where the relay circuit is provided, power supply in the given region becomes insufficient, causing increase in power supply voltage drop. This makes the circuit operation unstable, whereby problems such as malfunction and reduction in reliability may occur. Moreover, since the relay circuit must be supplied with power different from one supplied to its surroundings, the layout design may become difficult.

An objective of the present disclosure is providing a semiconductor integrated circuit device using buried power lines in which layout design can be easily made for a configuration that includes a standard cell supplied with power different from one supplied to its surroundings.

### SUMMARY

According to a mode of the present disclosure, a semiconductor integrated circuit device includes a circuit block including first and second standard cells, wherein the first standard cell includes a first buried power line extending in a first direction and supplying first power, and a first transistor of a first conductivity type, the first transistor is supplied with the first power from the first buried power line, the second standard cell includes a second buried power line extending in the first direction and supplying the first power, an upper-layer power line formed in a layer above the second buried power line and located to overlap the second buried power line in planar view, the upper-layer power line supplying second power, and a second transistor of the first conductivity type, and the second transistor is supplied with the second power from the upper-layer power line.

According to the above mode, the first standard cell includes the first buried power line that extends in the first direction and supplies the first power. The first transistor of the first standard cell is supplied with the first power from the first buried power line. The second standard cell includes: the second buried power line that extends in the first direction and supplies the first power; and the upper-layer power line that is in a layer above the buried power line and supplies the second power. The second transistor of the second standard cell is supplied with the second power from the upper-layer power line. The upper-layer power line overlaps the second buried power line in planar view. Therefore, the basic structure such as the placement of transistors and the positions of input/output pins can be shared by the first standard cell supplied with the first power from the buried power line and the second standard cell supplied with the second power from the upper-layer power line, whereby the layout design is facilitated.

According to the present disclosure, in a semiconductor integrated circuit device using buried power lines, layout design can be easily made for a configuration that includes a standard cell supplied with power different from one supplied to its surroundings.

### BRIEF DESCRIPTION OF THE DRAWINGS

FIG. 1 is a schematic view of a layout example of a semiconductor integrated circuit device according to the first embodiment.

FIG. 2 is a plan view showing an example of the layout structure of a cell 14 in FIG. 1.

FIG. 3 shows a circuit structure example of a buffer circuit.

FIG. 4 is a plan view showing an example of the layout structure of a cell 12 in FIG. 1.

FIG. 5 is a plan view showing another example of the layout structure of the cell 12 in FIG. 1.

FIG. 6 is a plan view showing yet another example of the layout structure of the cell 12 in FIG. 1.

FIG. 7 shows a layout structure example of a portion of block B in FIG. 1.

FIG. 8 is a cross-sectional view of the layout structure of FIG. 7.

FIG. 9 is a schematic view of a layout example of a semiconductor integrated circuit device according to the second embodiment.

FIG. 10 shows a circuit structure example of a level shifter circuit.

FIG. 11 is a plan view showing an example of the layout structure of a cell 22 in FIG. 9.

FIG. 12 shows a layout structure example of a portion of block E in FIG. 9.

### DETAILED DESCRIPTION

Embodiments of the present disclosure will be described hereinafter with reference to the accompanying drawings. In the following embodiments, it is assumed that the semiconductor integrated circuit device includes a plurality of standard cells (hereinafter simply called cells as appropriate) and at least some of the standard cells include fin field effect transistors (FETs).

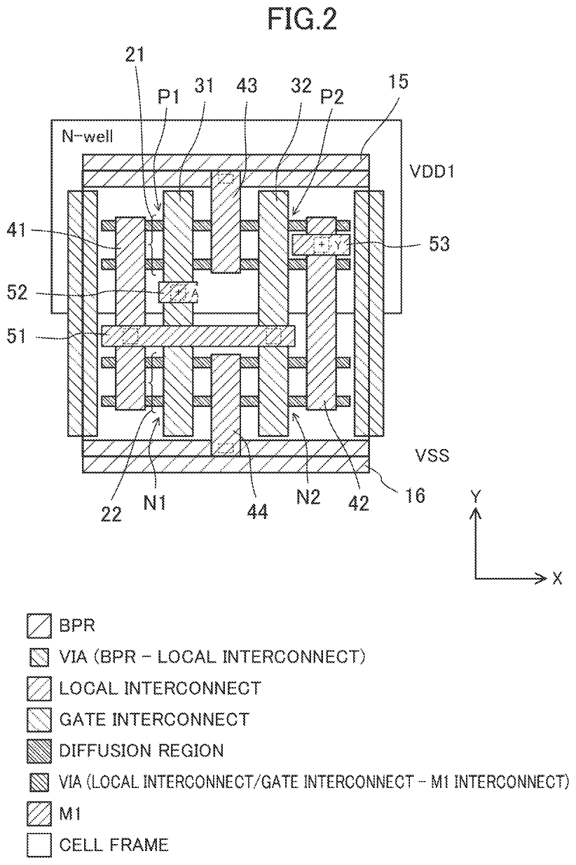

In the present disclosure, “VDD”, “VDD1”, “VDD2”, and “VSS” indicate power supply voltages or power itself. Also, hereinafter, in the plan views such as FIG. 2, the horizontal direction in the figure is called an X direction (corresponding to the first direction), the vertical direction in the figure is called a Y direction (corresponding to the second direction), and the direction perpendicular to the substrate plane is called a Z direction.

### First Embodiment

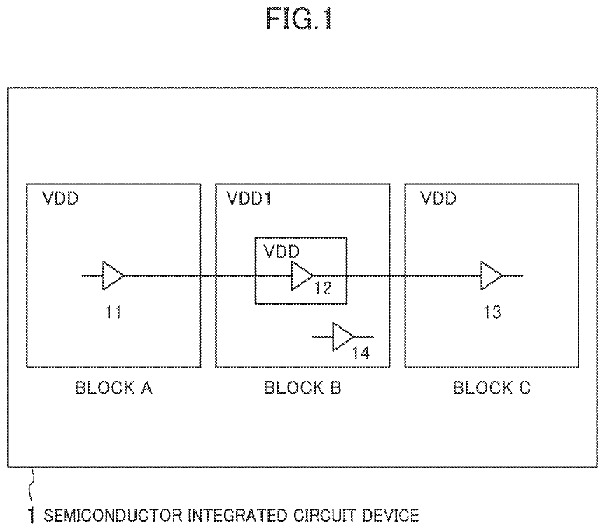

FIG. 1 is a schematic view of a layout example of a semiconductor integrated circuit device according to the first embodiment. The semiconductor integrated circuit device 1 of FIG. 1 includes blocks A, B, and C as circuit blocks. Each of the blocks A, B, and C includes standard cells (hereinafter called cells as appropriate): the block A includes a cell 11, the block B includes cells 12 and 14, and the block C includes a cell 13, among others. Note that, while the cells 11 to 14 are all illustrated as buffers in FIG. 1, the cells in the blocks are not limited to buffers.

Power VDD is supplied to cells in the blocks A and C. For example, VDD is supplied to the cell 11 in the block A and the cell 13 in the block C. VDD is always supplied during the operation of the semiconductor integrated circuit device 1.

Power VDD1 is supplied to cells in the block B. For example, VDD1 is supplied to the cell 14 in the block B. VDD1 is a kind of power supplied from VDD through a switch, and supply/shutoff of VDD1 is controlled with a control signal given to the switch.

The output signal of the cell 11 in the block A is transmitted to the cell 13 in the block C via the cell 12 (relay cell) in the block B. The cell 12 is supplied with VDD, not VDD1. If the power supplied to the cell 12 is VDD1, the cell 12 will not operate when VDD1 is shut off, failing to perform normal signal transmission. For this reason, the cell 12 is made to receive VDD although it is in the block B. With this, signal transmission from the cell 11 to the cell 13 is performed normally.

Note that, in place of the always-supplied power VDD, power VDD2 of which supply/shutoff is controlled with a control signal different from the one for VDD1 may be supplied to the blocks A and C and the cell 12 in the block B. In this case, also, signal transmission from the cell 11 to the cell 13 will be performed normally during the time when VDD2 is being supplied.

In FIG. 1, the configuration may be made so that two or more signals be transmitted from the block A to the block C. Also, two or more relay cells may be used to relay a signal transmitted from the block A to the block C. With this, longer distance signal transmission will be possible.

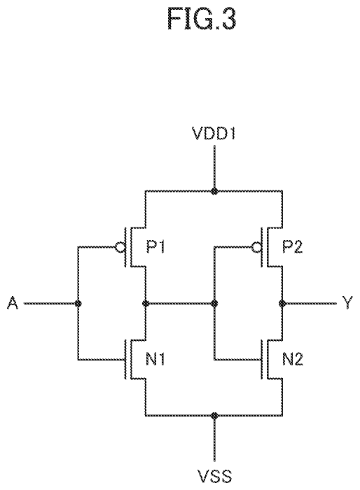

FIG. 2 is a plan view showing an example of the layout structure of the cell 14 in the block B. FIG. 3 is a circuit diagram of a buffer circuit implemented by the cell 14.

In the layout structure shown in FIG. 2, power lines 15 and 16 extending in the X direction are provided along both ends of the cell in the Y direction. The power lines 15 and 16 are both buried power rails (BPR) formed in a buried interconnect layer. The power line 15 supplies VDD1 and the power line 16 supplies VSS.

Two fins 21 extending in the X direction are provided in a p-type transistor region on an N-well, and two fins 22 extending in the X direction are provided in an n-type transistor region on a P-substrate. Gate interconnects 31 and 32 extend in the Y direction over the p-type transistor region and the n-type transistor region. The two fins 21 and the gate interconnect 31 constitute a fin FET P1, and the two fins 21 and the gate interconnect 32 constitute a fin FET P2. The two fins 22 and the gate interconnect 31 constitute a fin FET N1, and the two fins 22 and the gate interconnect 32 constitute a fin FET N2.

A local interconnect 41 extending in the Y direction is provided on left end portions of the fins 21 and 22 in the figure. The local interconnect 41 corresponds to an interconnect connecting the drains of the fin FETs P1 and N1. A local interconnect 42 extending in the Y direction is provided on right end portions of the fins 21 and 22 in the figure. The local interconnect 42 corresponds to an interconnect connecting the drains of the fin FETs P2 and N2. Center portions of the fins 21 are connected to the power line 15 through a local interconnect 43 extending in the Y direction and a via. Center portions of the fins 22 are connected to the power line 16 through a local interconnect 44 extending in the Y direction and a via.

In a metal interconnect layer (M1 interconnect layer), a metal interconnect 51 extending in the X direction is formed, which connects the local interconnect 41 and the gate interconnect 32 through vias. A metal interconnect 52, to which input A is given, is connected to the gate interconnect 31 through a via. A metal interconnect 53, which outputs output Y, is connected to the local interconnect 42 through a via.

The layout structures of the cell 11 in the block A and the cell 13 in the block C are similar to that of FIG. 2, but they are different in that the power line 15 supplies VDD, not VDD1.

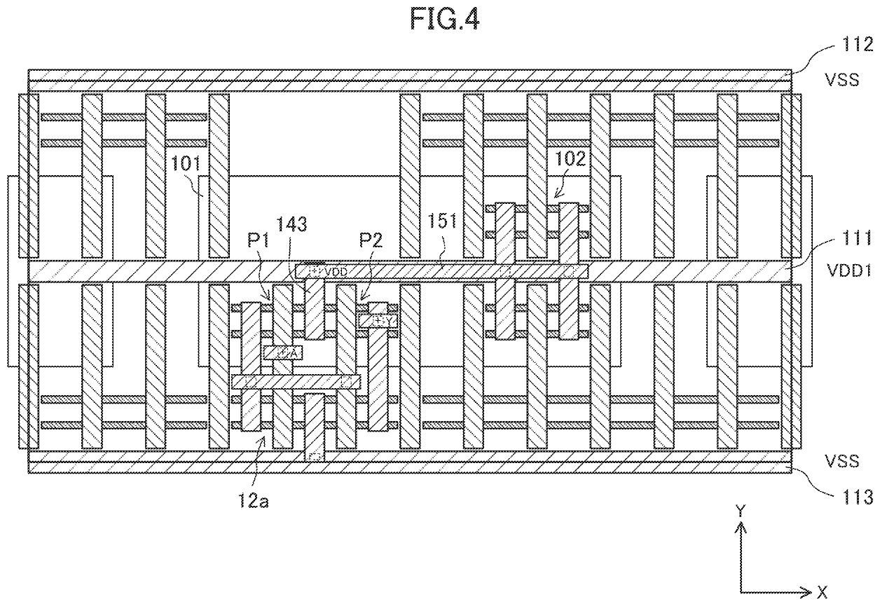

FIG. 4 is a plan view showing an example of the layout structure of the cell 12 in the block B, which is a so-called double-height cell. A power line 111 extending in the X direction is provided in a center portion of the cell in the Y direction. Power lines 112 and 113 extending in the X direction are provided along both ends of the cell in the Y direction.

The power lines 111, 112, and 113 are all buried power rails (BPR) formed in the buried interconnect layer. The power line 111 supplies VDD1 and the power lines 112 and 113 supply VSS.

In the layout structure of FIG. 4, a buffer circuit 12a is formed in a lower region with respect to the power line 111 in the figure. The layout structure of the buffer circuit 12a is similar to that of FIG. 2 and the circuit structure thereof is as shown in FIG. 3. However, a local interconnect 143 is not connected to the power line 111, but connected to a metal interconnect 151 formed in the upper metal interconnect layer (M1 interconnect layer). The metal interconnect 151, extending in the X direction, overlaps the power line 111 in planar view, and supplies VDD. That is, VDD is supplied to the sources of fin FETs P1 and P2 constituting the buffer circuit 12a.

In FIG. 4, an N-well 101 on which the fin FETs P1 and P2 are formed is isolated from N-wells around this. The layout structure of FIG. 4 includes a well tap 102 that supplies a well potential to the N-well 101. The well tap 102 connects the metal interconnect 151 and the N-well 101.

The layout structure of FIG. 4 includes, in addition to the buffer circuit 12a and the well tap 102, dummy gates, dummy fins, and dummy transistors that do not contribute to the logical operation of the circuit. These dummy gates, dummy fins, and dummy transistors are not necessarily required.

In the layout structure of FIG. 4, VDD is supplied from the metal interconnect 151 formed in the M1 interconnect layer to the buffer circuit 12a that transmits a signal. Therefore, by using the cell 12 as a relay cell, even though the buried power line 111 supplies VDD1 that is switched between supply and shutoff, signal transmission can be performed normally without being influenced by the supply/shutoff of VDD1.

Also, in the layout structure of FIG. 4, the buried power line 111 supplying VDD1 runs through in the X direction. Therefore, even though the cell 12 is placed in the block B, the buried power line supplying VDD1 does not become discontinuous.

Moreover, in the layout structure of FIG. 4, the metal interconnect 151 supplying VDD is placed to overlap the buried power line 111 supplying VDD1 in planar view. This facilitates the design of a standard cell. That is, in a standard cell using buried power lines, the basic structure such as the placement of transistors and the positions of input/output pins is made taking the laid positions of the buried power lines as a precondition. Therefore, by placing the power-supply metal interconnect to overlap a buried power line in planar view, the layout design can be performed without the need to change the basic structure such as the placement of transistors and the positions of input/output pins.

Also, since the metal interconnect 151 supplying VDD is placed to overlap the buried power line 111 in planar view, no transistor is formed under the metal interconnect 151. Therefore, since no increase in capacitance occurs between the metal interconnect 151 and a transistor, it is possible to prevent degradation in performance that may occur by controlling increase in capacitance between a power line and a transistor.

Note that the metal interconnect 151 supplying VDD does not necessarily need to overlap the buried power line 111 in planar view.

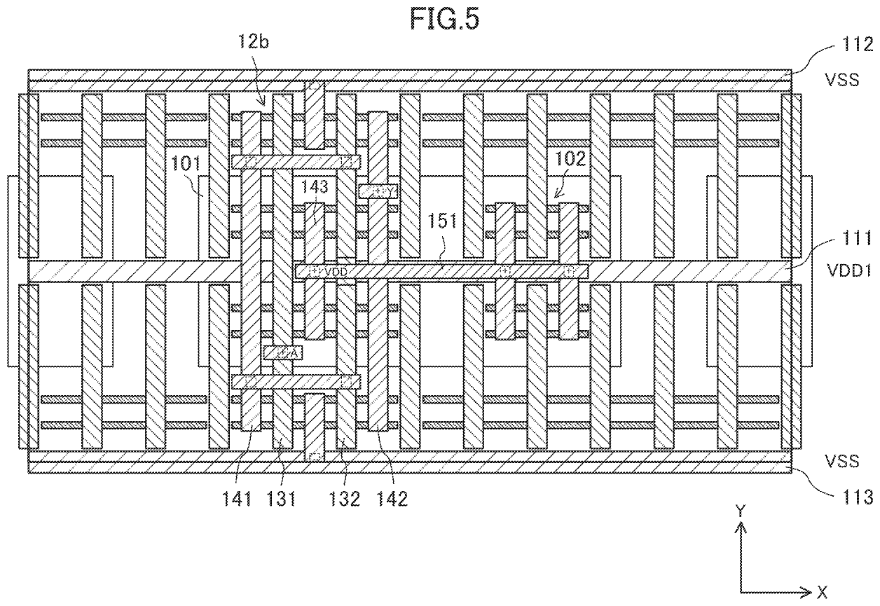

FIG. 5 is a plan view showing another example of the layout structure of the cell 12 in the block B As in the layout structure of FIG. 4, the layout structure of FIG. 5 is a double-height cell and includes buried power lines 111, 112, and 113. The power line 111 supplies VDD1 and the power lines 112 and 113 supply VSS.

In the layout structure of FIG. 5, a buffer circuit 12b is formed over upper and lower regions with respect to the power line 111 in the figure. The layout structure of the lower region of the buffer circuit 12b is similar to that of the buffer circuit 12a in FIG. 4. The layout structure of the upper region of the buffer circuit 12b corresponds to the inverted one of the layout structure of the lower region in the Y direction. Gate interconnects 131 and 132 and local interconnects 141, 142, and 143 are formed over the upper and lower regions in the figure. The local interconnect 143 is connected to the metal interconnect 151 supplying VDD formed in the upper metal interconnect layer.

The buffer circuit 12b shown in FIG. 5 corresponds to one having the circuit structure of FIG. 3 in which each of the transistors has four fins. That is, the buffer circuit 12b has a drive force double that of the buffer circuit 12a in FIG. 4, and therefore can drive a longer-distance signal line.

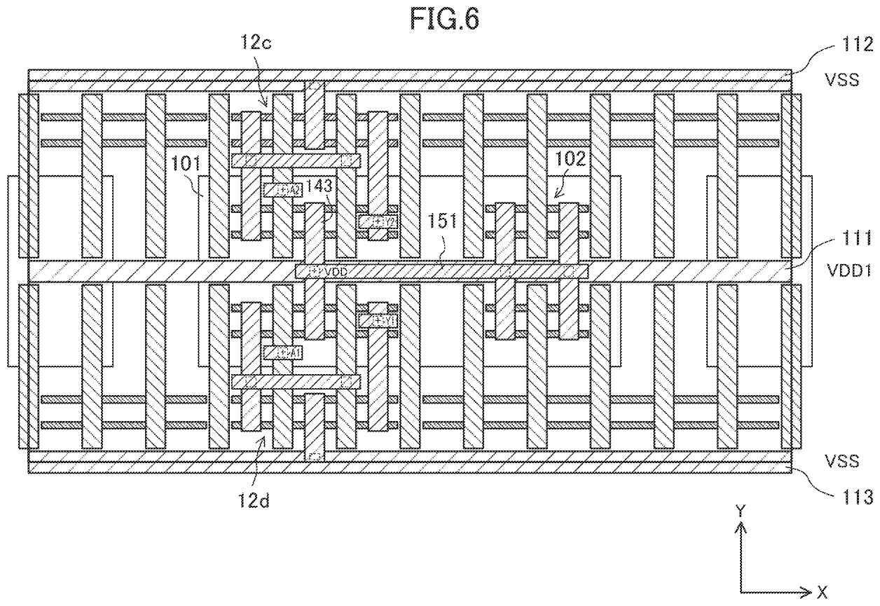

FIG. 6 is a plan view showing yet another example of the layout structure of the cell 12 in the block B. As in the layout structure of FIG. 4, the layout structure of FIG. 6 is a double-height cell and includes buried power lines 111, 112, and 113. The power line 111 supplies VDD1 and the power lines 112 and 113 supply VSS.

In the layout structure of FIG. 6, a buffer circuit 12c is formed in an upper region, and a buffer circuit 12d is formed in a lower region, with respect to the power line 111 in the figure. The layout structure of the buffer circuit 12d is similar to that of the buffer circuit 12a in FIG. 4. The layout structure of the buffer circuit 12c corresponds to the inverted one of the buffer circuit 12d in the Y direction. A local interconnect 143 is shared by the buffer circuits 12c and 12d, and connected to the metal interconnect 151 supplying VDD formed in the upper metal interconnect layer.

The buffer circuits 12c and 12d shown in FIG. 6 independently transmit different signals. That is, two signals can be transmitted by the cell 12 of FIG. 6. Therefore, compared to a case of placing two cells 12 each having the layout structure of FIG. 4, the layout area can be made smaller.

Note that three or more buffer circuits may be provided in the cell 12. Also, in the case of providing two or more buffer circuits, a configuration like the buffer circuit 12b in FIG. 5 may be included in such buffer circuits.

The layout structures of FIGS. 5 and 6 can also obtain similar effects to those obtained by the layout structure of FIG. 4. Moreover, since the metal interconnect 151 supplying VDD is placed in a center portion in the Y direction and circuits are placed above and below the metal interconnect 151 in the Y direction, an additional effect that power supply becomes equal for the upper and lower parts of the double-height cell is obtained.

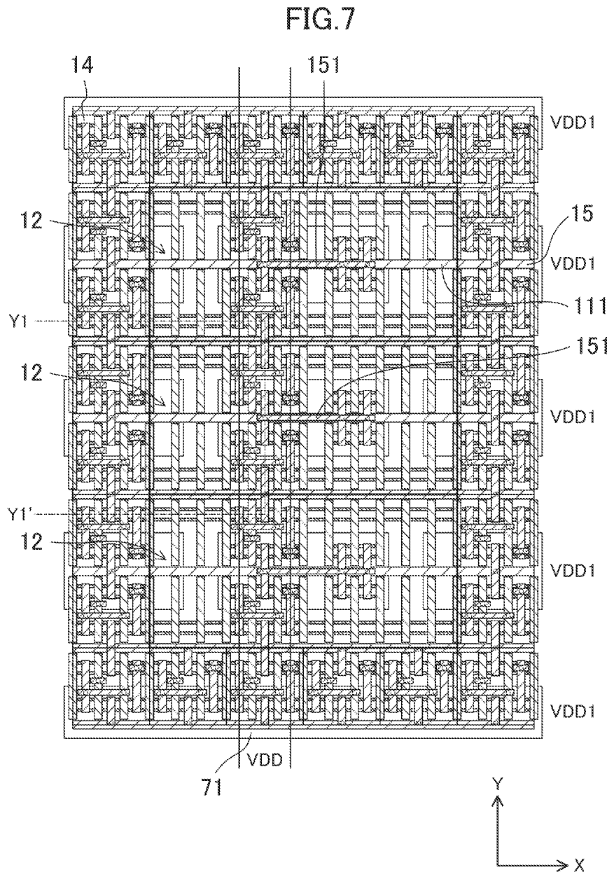

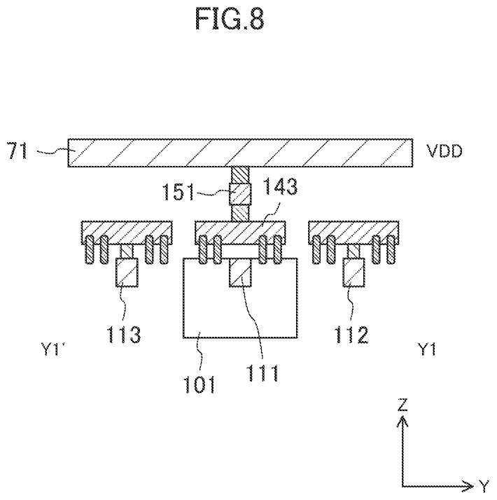

FIG. 7 shows a layout structure example of a portion of the block B. Note that, in FIG. 7, illustration of some signal lines and power lines is omitted for easy understanding of the drawing. FIG. 8 shows a cross-sectional structure along line Y1-Y1′ in FIG. 7.

In FIG. 7, three cells 12 each having the layout structure of FIG. 6 are arranged in line in the Y direction in the center. Cells 14 each having the layout structure of FIG. 2 are placed surrounding the three cells 12. The power VDD1 is supplied to the cells 14 through the buried power lines 15. Since the buried power lines 111 are provided in the cells 12, buried power lines extending in the X direction are formed continuously in the block layout.

In an M2 interconnect layer located above the M1 interconnect layer, formed is a power line 71 extending in the Y direction over the entire block layout. The power line 71 supplies the power VDD and is connected to the metal interconnects 151 of the cells 12 through vias. The power line 71 may otherwise be formed in an interconnect layer other than the M2 interconnect layer.

As described earlier, the cell 12 having the layout structure of FIG. 6 can transit two signals. Therefore, in the configuration of FIG. 7, a total of six signals can be transmitted by the three cells 12. Each of the cells 12 is supplied with VDD from the power line 71 through the metal interconnect 151.

While it is assumed that the cells 14 entirely surround the cells 12 in the layout of FIG. 7, cells supplied with VDD1 other than the cells 14 may be placed around the cells 12. Also, the number of cells 12 arranged is not limited to three. The layout structure of the cells 12 is not limited to the one shown in FIG. 6, but may be the layout structure of FIG. 4 or FIG. 5, for example.

As described above, in this embodiment, the cell 14 includes the buried power line 15 extending in the X direction and supplying VDD1. Transistors of the cell 14 are supplied with VDD1 from the buried power line 15. The cell 12 includes the buried power line 111 extending in the X direction and supplying VDD1 and the upper-layer power line 151 located above the buried power line 111 and supplying VDD. Transistors of the cell 12 are supplied with VDD from the upper-layer power line 151. The upper-layer power line 151 overlaps the buried power line 111 in planar view. Therefore, the basic structure such as the placement of transistors and the positions of input/output pins can be shared by the cell 14 supplied with VDD1 from the buried power line 15 and the cell 12 supplied with VDD from the upper-layer power line 151, whereby the layout design is facilitated.

### Second Embodiment

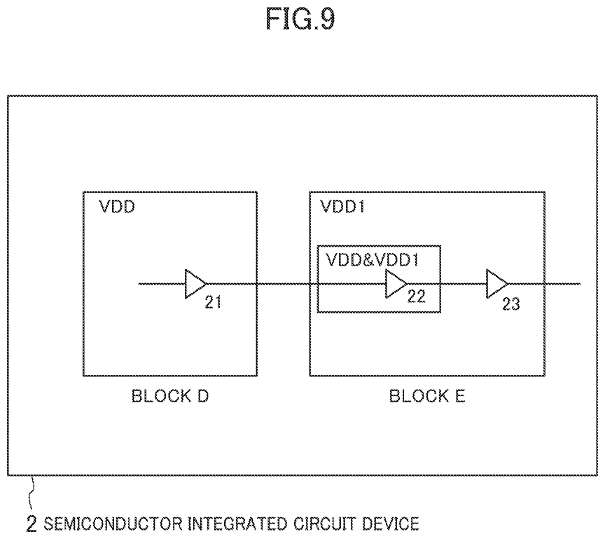

FIG. 9 is a schematic view of a layout example of a semiconductor integrated circuit device according to the second embodiment. The semiconductor integrated circuit device 2 of FIG. 9 includes blocks D and E as circuit blocks. Each of the blocks D and E includes standard cells: the block D includes a cell 21, and the block E includes cells 22 and 23, among others. The cells 21 and 23 each have a layout structure similar to that of the cell 14 in the first embodiment, for example.

Power VDD is supplied to cells in the block D. For example, VDD is supplied to the cell 21 in the block D. The output signal of the cell 21 is transmitted to the block E.

Power VDD1 is supplied to cells in the block E. For example, VDD1 is supplied to the cell 23 in the block E. Assume here that the power supply voltage VDD1 is higher than the power supply voltage VDD. The cell 22 receives the signal from the cell 21 and outputs it to the cell 23. Since the power supply voltage is different between the blocks D and E, the amplitude of the signal received from the cell 21 is different from the amplitude of the signal output to the cell 23. The cell 22 is therefore a level shifter cell having a level shifting function of changing the amplitude of a signal. Note that the cell 22 has a buffer function and does not change the logic of a signal.

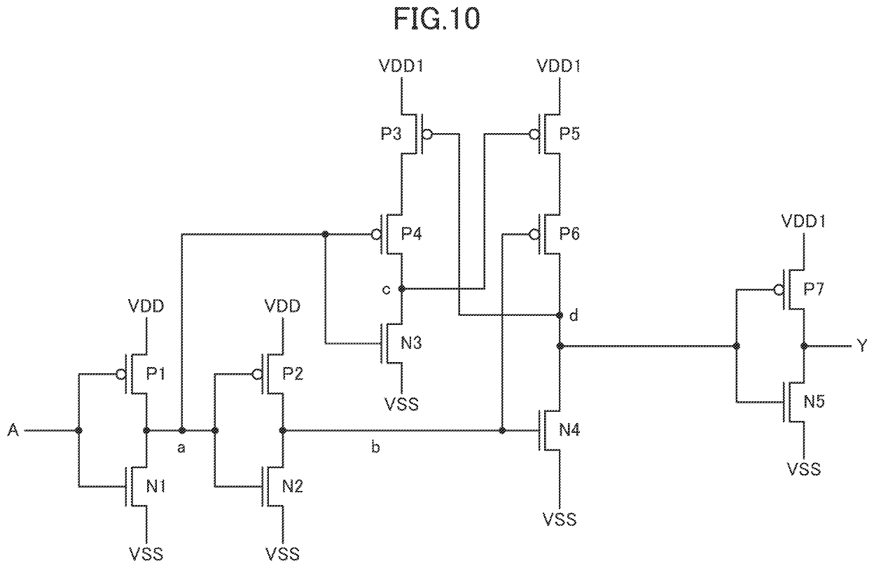

FIG. 10 shows a circuit structure example of a level shifter, and the cell 22 has the circuit structure shown in FIG. 10, for example. As shown in FIG. 10, the cell 22 needs to be supplied with both the power VDD and the power VDD1. In the circuit of FIG. 10, VDD is supplied to an inverter constituted by transistors P1 and N1 and an inverter constituted by transistors P2 and N2, and VDD1 is supplied to the subsequent part of the circuit.

When input A is LOW, node a=HIGH (VDD) and node b=LOW. At this time, a transistor N3 is ON, a transistor N4 is OFF, and node c=LOW. This turns ON a transistor P5, allowing a current to flow from VDD1 through the transistor P5 and a transistor P6, whereby node d=HIGH (VDD1). As a result, output Y becomes LOW. On the other hand, when the input A is HIGH, node a=LOW and node b=HIGH (VDD). At this time, the transistor N3 is OFF, the transistor N4 is ON, and node d=LOW. This turns ON a transistor P3, allowing a current to flow from VDD1 through the transistor P3 and a transistor P4, whereby node c=HIGH (VDD1). As a result, the output Y becomes HIGH (VDD1).

By the operation described above, the signal A with an amplitude VDD is converted to the signal Y with an amplitude VDD1.

Note that the power supply voltages VDD and VDD1 do not necessarily need to be always different from each other. For example, in some configurations, the power supply voltage VDD1 may change, becoming the same as or different from the power supply voltage VDD. In such configurations, also, a level shifter cell is necessary for the case of the power supply voltages VDD and VDD1 being different from each other.

While the cell 22 is described as having a buffer function, the configuration is not limited to this. The cell 22 may be a level shifter cell having a logical function such as an inverter and the like.

The signal transmitted from the block D to the block E is not limited to a single signal, but two or more signals may be transmitted.

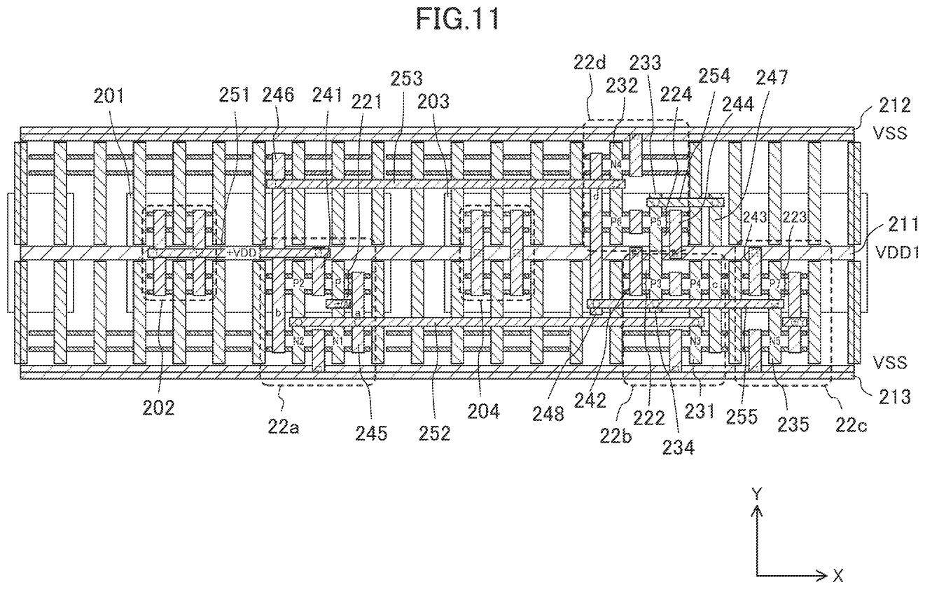

FIG. 11 is a plan view showing an example of the layout structure of the cell 22 in the block E, which is a double-height cell. A power line 211 extending in the X direction is provided in a center portion of the cell in the Y direction. Power lines 212 and 213 extending in the X direction are provided along both ends of the cell in the Y direction. The power lines 211, 212, and 213 are all buried power rails (BPR) formed in a buried interconnect layer. The power line 211 supplies VDD1 and the power lines 212 and 213 supply VSS. A metal interconnect 251, which is to be an upper-layer power line, is formed in an M1 interconnect layer. The metal interconnect 251, extending in the X direction, overlaps the power line 211 in planar view, and supplies VDD.

The layout structure of FIG. 11 corresponds to the circuit structure of FIG. 10. In FIG. 11, the symbols of the transistors and nodes in FIG. 10 are indicated at their corresponding positions.

In the layout structure of FIG. 11, a circuit part 22a including fin FETs P1, P2, N1, and N2 is formed in a lower region with respect to the power line 211 in the figure. A local interconnect 241 extending in the Y direction connects center portions of fins 221, which are to be the sources of the fin FETs P1 and P2, and the metal interconnect 251. That is, VDD is supplied to the sources of the fin FETs P1 and P2.

An N-well 201 on which the fin FETs P1 and P2 are formed is isolated from N-wells around this. The layout structure of FIG. 11 includes a well tap 202 that supplies a well potential to the N-well 201. The well tap 202 connects the metal interconnect 251 and the N-well 201.

A circuit part 22b including fin FETs P3, P4, and N3 and a circuit part 22c including fin FETs P7 and N5 are formed in a lower region with respect to the power line 211 in the figure. A circuit part 22d including fin FETs P5, P6, and N4 is formed in an upper region with respect to the power line 211 in the figure.

A local interconnect 242 extending in the Y direction connects left end portions of fins 222, which are to be the source of the fin FET P3, to the power line 211 through a via. A local interconnect 243 extending in the Y direction connects left end portions of fins 223, which are to be the source of the fin FET P7, to the power line 211 through a via. A local interconnect 244 extending in the Y direction connects right end portions of fins 224, which are to be the source of the fin FET P5, to the power line 211 through a via. That is, VDD1 is supplied to the sources of the fin FETs P3, P5, and P7.

In the circuit part 22a, a local interconnect 245 corresponding to the node a is connected to a gate interconnect 231 in the circuit part 22b through an M1 interconnect 252 extending in the X direction. In the circuit part 22a, a local interconnect 246 corresponding to the node b extends to an upper region with respect to the power line 211 and is further connected, through an M1 interconnect 253 extending in the X direction, to a gate interconnect 232 in the circuit part 22d. In the circuit part 22b, a local interconnect 247 corresponding to the node c extends to an upper region with respect to the power line 211 and is further connected, through an M1 interconnect 254 extending in the X direction, to a gate interconnect 233 in the circuit part 22d. In the circuit part 22d, a local interconnect 248 corresponding to the node d extends to a lower region with respect to the power line 211 and is further connected, through an M1 interconnect 255 extending in the X direction, to a gate interconnect 234 in the circuit part 22b and to a gate interconnect 235 in the circuit part 22c.

The layout structure of FIG. 11 includes a well tap 204 that supplies a well potential to an N-well 203 on which the fin FETs P3 to P7 are formed. The well tap 204 connects the power line 211 and the N-well 203.

In the layout structure of FIG. 11, VDD is supplied to the circuit part 22a from the metal interconnect 251 formed in the M1 interconnect layer. Therefore, using the cell 22, even though the buried power line 211 supplies VDD1, the circuit normally operates with no influence of this supply.

Also, in the layout structure of FIG. 11, the buried power line 211 supplying VDD1 runs through in the X direction. Therefore, even though the cell 22 is placed in the block E, the buried power line supplying VDD1 does not become discontinuous.

Moreover, in the layout structure of FIG. 11, the metal interconnect 251 supplying VDD is placed to overlap the buried power line 211 supplying VDD1 in planar view. This facilitates the design of a standard cell. That is, in a standard cell using buried power lines, the basic structure such as the placement of transistors and the positions of input/output pins is made taking the laid positions of the buried power lines as a precondition. Therefore, by placing the power-supply metal interconnect to overlap a buried power line in planar view, the layout design can be performed without the need to change the basic structure such as the placement of transistors and the positions of input/output pins.

Also, since the metal interconnects 251 supplying VDD is placed to overlap the buried power line 211 in planar view, no transistor is formed under the metal interconnect 251. Therefore, since no increase in capacitance occurs between the metal interconnect 251 and a transistor, it is possible to prevent degradation in performance that may occur by controlling increase in capacitance between a power line and a transistor.

In the layout structure of FIG. 11, since the metal interconnect 251 supplying VDD is placed in a center portion in the Y direction and transistors are placed above and below the metal interconnect 251 in the Y direction, an additional effect that power supply becomes equal for the upper and lower parts of the double-height cell is obtained.

The metal interconnect 251 supplying VDD does not necessarily need to overlap the buried power line 211 in planar view.

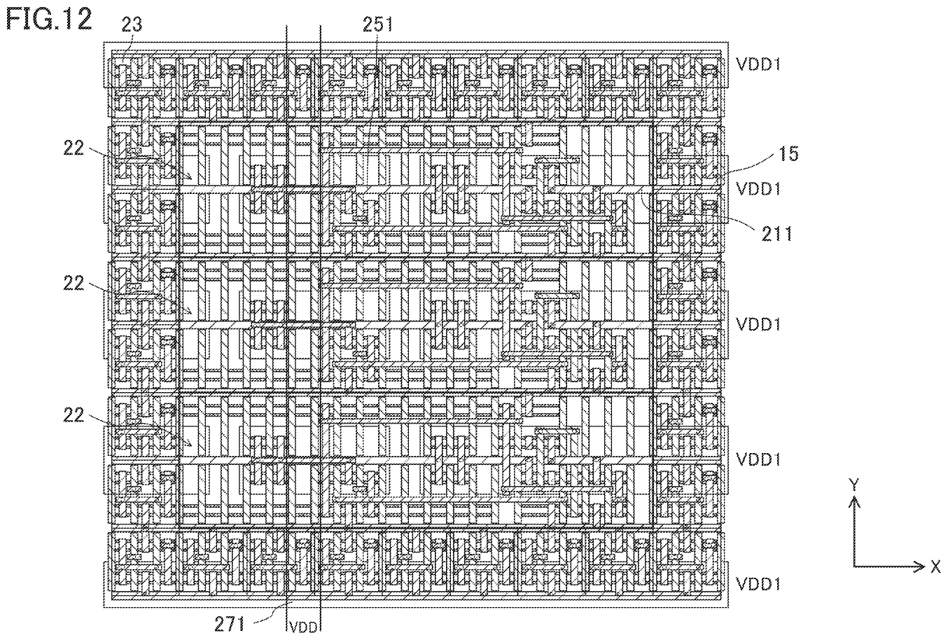

FIG. 12 shows a layout structure example of a portion of the block E. Note that, in FIG. 12, illustration of some signal lines and power lines is omitted for easy understanding of the drawing.

In FIG. 12, three cells 22 each having the layout structure of FIG. 11 are arranged in line in the Y direction in the center. Cells 23 each having a layout structure similar to that of FIG. 2 are placed surrounding the three cells 22. VDD1 is supplied to the cells 23 through the buried power lines 15. Since the buried power lines 211 are provided in the cells 22, buried power lines extending in the X direction are formed continuously in the block layout.

In an M2 interconnect layer located above the M1 interconnect layer, formed is a power line 271 extending in the Y direction over the entire block layout. The power line 271 supplies VDD and is connected to the metal interconnects 251 of the cells 22 through vias. The power line 271 may otherwise be formed in an interconnect layer other than the M2 interconnect layer.

The cell 22 having the layout structure of FIG. 11 can convert the amplitude of a signal. Therefore, in the configuration of FIG. 12, amplitude conversion of three signals is possible by the three cells 22. Each of the cells 22 is supplied with VDD from the power line 271 through the metal interconnect 251. Also, each cell 22 is supplied with VDD1 from the buried power line 211.

While it is assumed that the cells 23 entirely surround the cells 22 in the layout of FIG. 12, cells supplied with VDD1 other than the cells 23 may be placed around the cells 22. Also, the number of cells 22 placed is not limited to three. The layout structure of the cells 22 is not limited to the one shown in FIG. 11.

As described above, in this embodiment, the cell 23 includes the buried power line 15 extending in the X direction and supplying VDD1. Transistors of the cell 23 are supplied with VDD1 from the buried power line 15. The cell 22 includes the buried power line 211 extending in the X direction and supplying VDD1 and the upper-layer power line 251 located above the buried power line 211 and supplying VDD. Transistors of the cell 22 are supplied with VDD from the upper-layer power line 251. The upper-layer power line 251 overlaps the buried power line 211 in planar view. Therefore, the basic structure such as the placement of transistors and the positions of input/output pins can be shared by the cell 23 supplied with VDD1 from the buried power line 15 and the cell 22 supplied with VDD from the upper-layer power line 251, whereby the layout design is facilitated.

While the semiconductor integrated circuit device was illustrated as including standard cells having fin FETs in the above description, the transistors of the standard cells are not limited to fin FETs. For example, the present disclosure is also applicable to a semiconductor integrated circuit device including standard cells having nanosheet FETs.

According to the present disclosure, in a semiconductor integrated circuit device using buried power lines, layout design can be easily made for a configuration that includes a standard cell supplied with power different from one supplied to its surroundings. The present disclosure is therefore useful for improving the development efficiency, and reducing the cost, of system LSI, for example.

1. A semiconductor integrated circuit device, comprising a circuit block including first and second standard cells,
wherein
the first standard cell includes
a first buried power line extending in a first direction and supplying first power, and
a first transistor of a first conductivity type,
the first transistor is supplied with the first power from the first buried power line,
the second standard cell includes
a second buried power line extending in the first direction and supplying the first power,
an upper-layer power line formed in a layer above the second buried power line and located to overlap the second buried power line in planar view, the upper-layer power line supplying second power, and
a second transistor of the first conductivity type, and
the second transistor is supplied with the second power from the upper-layer power line.

2. The semiconductor integrated circuit device of claim 1, wherein
the first and second standard cells are adjacent to each other in the first direction, and
the first buried power line and the second buried power line are formed continuously in the first direction.

3. The semiconductor integrated circuit device of claim 1, wherein
the second standard cell includes
a well of a second conductivity type, and
a well tap configured to supply a potential to the well,
the second transistor is formed on the well, and
the well tap is electrically connected to the upper-layer power line.

4. The semiconductor integrated circuit device of claim 1, wherein
the second standard cell is a double-height cell, and
the second buried power line and the upper-layer power line are placed in a center portion of the second standard cell in a second direction perpendicular to the first direction.

5. The semiconductor integrated circuit device of claim 4, wherein
the second standard cell includes a third transistor of the first conductivity type,
the third transistor is supplied with the second power from the upper-layer power line, and
the second and third transistors are placed on opposite sides of the upper-layer power line in the second direction.

6. The semiconductor integrated circuit device of claim 5, wherein
the second standard cell includes a buffer circuit configured to transmit a single signal, and
the buffer circuit includes the second and third transistors.

7. The semiconductor integrated circuit device of claim 5, wherein
the second standard cell includes first and second buffer circuits configured to transmit mutually independent signals,
the first buffer circuit includes the second transistor, and
the second buffer circuit includes the third transistor.

8. The semiconductor integrated circuit device of claim 4, wherein
the second standard cell includes a third transistor of the first conductivity type, and
the third transistor is supplied with the first power from the second buried power line.

9. The semiconductor integrated circuit device of claim 1, wherein
the circuit block includes
a second upper-layer power line placed above the upper-layer power line to extend in a second direction perpendicular to the first direction, and
the upper-layer power line is electrically connected to the second upper-layer power line.
